(19) United States
(12) Patent Application Publication
(10) Pub. No.: US 2026/0229457 A1
(43) Pub. Date: Aug. 6, 2026

(54) Transformer Coupled Plasma Source with Uniformity Control Mechanisms for Small-Volume Chambers

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/044,592

(22) Filed: Feb. 3, 2025

(51) Int. Cl. H01J 37/32

(52) U.S. Cl. CPC H01J 37/3211; H01J 37/32146; H01J 2237/334

(57) ABSTRACT

Disclosed herein are systems and methods for a transformer-coupled plasma (TCP) source with uniformity control mechanisms, particularly for small plasma process chambers. The TCP source includes a center coil, an edge coil, and a middle coil. The center and edge coils receive a first pulsed RF power at a first frequency, while the middle coil receives a second pulsed RF power at a substantially lower frequency. Each pulse of the second RF power overlaps with a pulse of the first RF power to enhance plasma uniformity.

### FIELD OF INVENTION

The present invention relates to plasma processing systems and, more particularly, to a transformer coupled plasma (TCP) source with an improved coil configuration for enhanced plasma uniformity, particularly in smaller process chambers.

### BACKGROUND

Transformer coupled plasma (TCP) sources are widely used in semiconductor processing for etching and deposition, including atomic layer etching (ALE). Conventional TCP sources typically employ a center coil and an edge coil to shape plasma distribution. In large process chambers, where the distance between the plasma source and the substrate is greater, plasma uniformity is primarily achieved through the diffusion of ions and radicals. However, in smaller chambers with a plasma volume of less than 10 liters, diffusion alone is insufficient to maintain uniform plasma distribution, leading to localized variations in plasma density.

For ALE, a smaller plasma volume is often required to facilitate fast gas exchange between a surface modification step and a sputtering step. However, in such small chambers, managing plasma uniformity becomes more challenging. The conventional center and edge coil configuration can result in non-uniform plasma characteristics, particularly in the region between the coils where power deposition is less controlled. This non-uniformity affects ion flux and radical distribution across the substrate, leading to inconsistencies in ALE and other plasma-based processes. Without an effective mechanism to regulate plasma uniformity in this intermediate region, process repeatability and yield in small-volume chambers may be compromised.

### SUMMARY

In some embodiments, a plasma source for a process system includes a transformer coupled plasma (TCP) source configured with a center coil, a middle coil, and an edge coil. The middle coil, which may be a single turn, is positioned between the center and edge coils to improve plasma uniformity, particularly in smaller process chambers with a plasma volume of less than 10 liters.

In some implementations, the middle coil receives RF power at a substantially lower frequency compared to the center and edge coils. The lower frequency operation of the middle coil enhances ionization efficiency, enriches plasma modes and improves uniformity in the region between the center and edge coils, mitigating plasma density variations commonly observed in conventional two-coil configurations.

In some embodiments, the RF power supplied to the center and edge coils follows a first pulsing scheme, while the RF power supplied to the middle coil follows a second pulsing scheme. The pulses of the first and second pulsing schemes may overlap, and in some implementations, a delay is introduced between the pulses to optimize plasma characteristics. The synchronization and timing of these pulses ensure stable plasma generation and sustainment for the overlapped pulses to mitigate issues arising from difficulties in igniting plasma for electronegative gases like chlorine, particularly at lower frequencies.

In some implementations, various configurations may be employed for coupling the coils to RF power generators. In some embodiments, a single RF power generator supplies power to both the center and edge coils through an RF power divider, while a separate RF power generator is used for the middle coil. In other embodiments, each coil is coupled to an independent RF power generator, allowing for precise control of frequency, power levels, and pulsing schemes. In still other embodiments, all coils are coupled to a single RF power generator which utilizes a RF power divider to distribute the RF power.

The disclosed configurations provide improved plasma uniformity, particularly in small-volume process chambers, and enhance process stability by optimizing power distribution and pulsing control among multiple coils.

### BRIEF DESCRIPTIONS OF THE DRAWINGS

The clarity of the embodiments is enhanced by referring to the following description in conjunction with the accompanying drawings:

FIG. 1: Illustrates an exemplary plasma process system incorporating a TCP source with a center coil, a middle coil, and an edge coil.

FIG. 2: Depicts a schematic of the TCP source, showing the spatial arrangement of the center, middle, and edge coils.

FIG. 3A: Demonstrates a first embodiment of the TCP source, where the center and edge coils are driven by a first RF power generator with an RF power divider, while the middle coil is driven by a second RF power generator.

FIG. 3B: Highlights a second embodiment of the TCP source, where the center, middle, and edge coils are driven by a single RF power generator with a three-way RF power divider.

FIG. 3C: Illustrates a third embodiment of the TCP source, where the center, middle, and edge coils are each driven by independent RF power generators.

FIG. 4: Depicts exemplary pulsed RF power waveforms for the first and second RF power generators according to the first embodiment, where each pulse from the second RF power generator overlaps with a pulse from the first RF power generator with a delay.

FIG. 5: Presents a flowchart illustrating the operations of the first embodiment of the TCP source.

### DETAILED DESCRIPTIONS

To foster a comprehensive understanding, this description elaborates on specific implementations of the current invention. While specific details are provided for elucidation, adjustments and variations that align with the following claims are deemed acceptable. Some established procedures and components are selectively detailed to underscore the unique facets of the invention.

### Terms Used

Transformer Coupled Plasma (TCP) source: A plasma source comprising a center coil, a middle coil, and an edge coil for generating and sustaining plasma within a process chamber.

Plasma Volume: The spatial region within the process chamber where plasma is generated and sustained. In some embodiments, a small plasma volume refers to a chamber with a plasma volume of less than 10 liters, facilitating fast gas exchange in processes such as atomic layer etching (ALE).

Plasma Mode: The operational state of the plasma determined by RF power frequency, power levels, and pulsing schemes.

RF Power Generator: A device supplying RF power to sustain plasma, operating at different frequencies and pulsing schemes to optimize process performance.

Pulsing: A technique where RF power is delivered in pulses rather than continuously. The pulses from multiple RF power generators may be synchronized or include delays to enhance plasma characteristics.

Resonator: A component used to match RF impedance, ensuring efficient power coupling between RF power generators and plasma.

Electrostatic Chuck (ESC): A chuck that secures the substrate using electrostatic forces, ensuring uniform clamping and temperature control during plasma processing.

Bias Unit: A unit that applies an RF power generator or a tailored waveform generator to the ESC to enhance ion energy during etching.

Gas Distribution Unit: A system that introduces process gases into the chamber, which may include injectors, a showerhead, or side injection.

Vacuum Chamber: An enclosed low-pressure environment where plasma-based semiconductor processes occur.

Atomic Layer Etching (ALE): A plasma-based etching process that removes material layer by layer through alternating surface modification and sputtering steps.

System Controller: A control unit that manages RF power, gas flow, and pulsing schemes, ensuring process control.

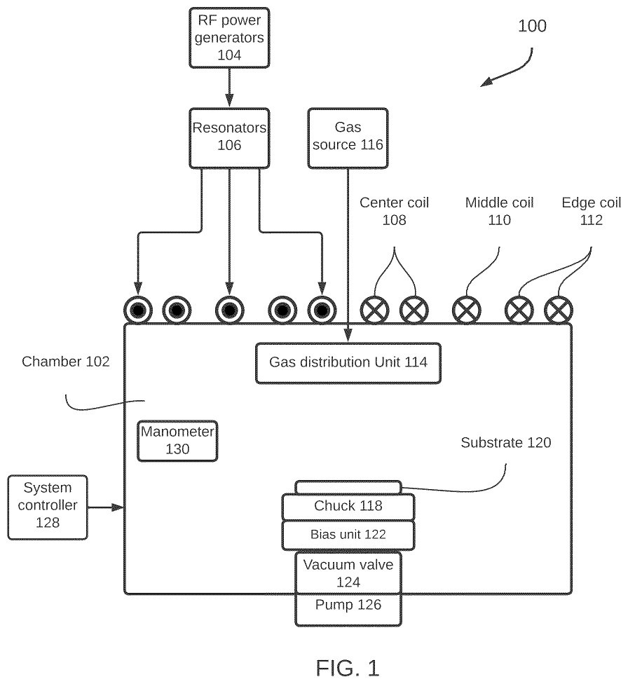

FIG. 1 illustrates a schematic diagram of a process system, denoted as 100. The process system 100 includes a vacuum chamber 102, which is configured to conduct a plasma-based process. Atop the chamber 102 is a TCP source configured to receive RF power and generate plasma within the chamber 102. The TCP source is powered by RF generators 104 and resonators 106. The TCP source includes a center coil 108, a middle coil 110, and an edge coil 112. The coils may be driven by a single RF power generator with a power divider or by two or three RF power generators, each of which can be operated at different frequencies, power levels, and pulsing schemes. Each coil may have a single turn or multiple turns. In a preferred implementation, the center and edge coils (108, 112) have multiple turns, while the middle coil 110 has a single turn. For a small chamber with a plasma volume of less than 10 liters, the middle coil 110 can significantly improve plasma uniformity. The center and edge coils (108, 112) may be operated at 13.56 MHz, while the middle coil 110 may be operated at a substantially lower frequency, such as, for example, 2 MHz. It should be noted that various frequencies, such as 13.56 MHz, 2 MHz, 1 MHz, 400 kHz, and 100 kHz, can be adopted for each coil or any combination of the coils with an RF power divider, depending on specific applications.

Referring back to FIG. 1, a gas distribution unit 114 draws gases from a gas source 116 via a gas box, mass flow controllers (MFCs), and valves (not shown in the Figure). The gas distribution unit 114 can be configured as a showerhead or an injector, depending on the design. In some implementations, a side injection mechanism may also be used. A gas manifold may be adopted to mix the gases prior to their introduction into the process chamber 102. In an ALE process, two gases are typically used. For example, in a silicon ALE, chlorine gas is used for a surface modification step to form a chemically modified layer, and argon is employed for a sputtering step to remove the modified layer.

Within the lower portion of the chamber 102, a chuck 118 supports a substrate 120 during processing. The chuck 118 is typically an electrostatic chuck (ESC) designed for etching processes. To increase ion energy during etching or specifically during the sputtering step of the ALE, a bias unit 122 is employed when the chamber's plasma is ignited. Depending on the design, the bias unit 122 can be an RF power generator connected to the chuck 118 via a blocking capacitor or a tailored waveform generator specifically configured for this purpose.

Gases, including reaction by-products, are evacuated from the chamber 102 by a pump 126. A vacuum valve 124, located upstream of the pump, regulates the gas removal rate. The evacuated gases are directed to an exhaust via an exhaust line (not shown in the Figure). The chamber's pressure is controlled by balancing the injection and removal rates of gases, with a proportional-integral-derivative (PID) control loop adjusting the pressure based on readings from a manometer 130.

The operations of the process system 100 are coordinated by a system controller 128, which comprises a computer and various software modules. The system controller 128 receives a process recipe and coordinates the process for generating plasma within the chamber 102.

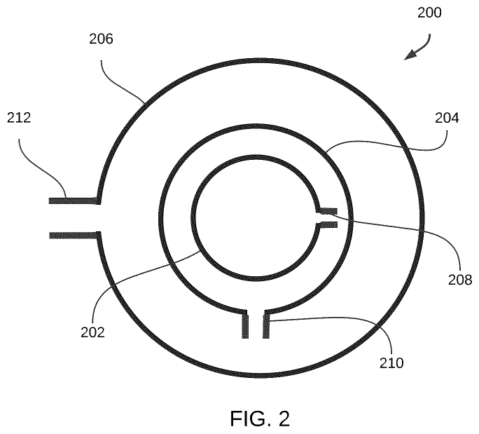

Referring to FIG. 2, an example of the top view (200) of three concentric coils is shown to improve plasma uniformity within the chamber 102. The plasma source includes a center coil 202, a middle coil 204, and an edge coil 206. The center coil 202 is coupled to an RF power generator via a pair of connectors 206, the middle coil 204 via connector 208, and the edge coil 206 via connector 210. Although only a single coil turn is shown in FIG. 2, the coils may include multiple turns, and various geometries may be utilized. The designs of the connectors shown in FIG. 2 are for illustration only. The connectors can be designed with many variations as known in the art.

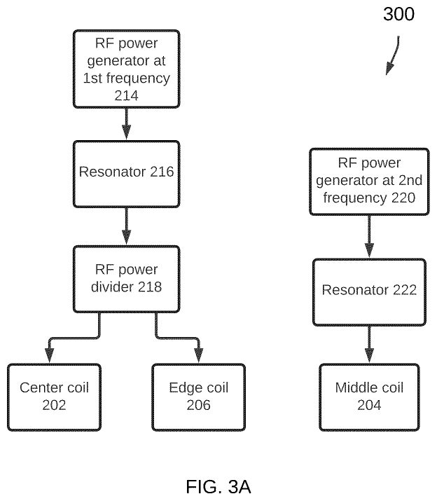

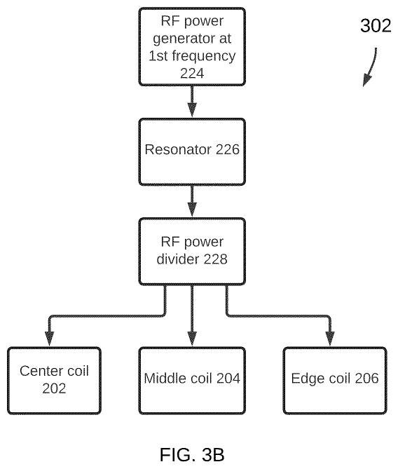

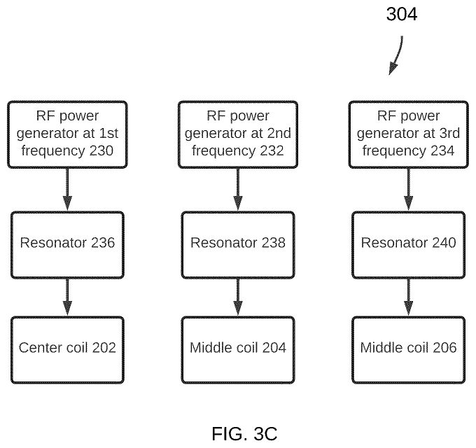

In the first embodiment, shown as 300 in FIG. 3A, the center coil 202 and the edge coil 206 are coupled to an RF power generator 214, which is operated at the first frequency via a resonator 216. An RF power divider 218 is placed between the resonator 216 and the coils (202, 206), distributing RF power between the center coil 202 and the edge coil 206. The division ratio may be specified by a process recipe. For example, the center coil 202 may receive 60% of the RF power from the RF power generator 214, while the edge coil 206 receives the remaining 40%. The first operating frequency may be 13.56 MHz, 2 MHz, 1 MHz, 400 kHz, or 100 kHz.

The middle coil 204 is coupled to a separate RF power generator 220 via a resonator 222, which is operated at the second frequency. The second frequency may be substantially lower than the first frequency. For example, if the first frequency is 13.56 MHz, the second frequency can be selected as 2 MHz. Multiple frequencies may enrich plasma states and improve process performance.

If the same frequency is used for the generators 214 and 220, the phases of the respective RF power may be different. For example, the middle coil may receive RF power which has 180 degree phase difference comparing to the RF power from the power generator 214.

The RF power from the RF power generators 214 and 220 may also be pulsed. The pulse schemes for the two generators may also be different.

In the second embodiment, shown as 302 in FIG. 3B, the coils (202, 204, 206) are coupled to an RF power generator 224 via a resonator 226. All three coils receive RF power at the same frequency. An RF power divider 228 is utilized to distribute the RF power to the three coils. For example, the center coil 202 receives 30%, the middle coil 204 receives 30%, and the edge coil 206 receives 40%.

In the third embodiment, shown as 304 in FIG. 3C, each coil is coupled to a separate RF power generator. The center coil 202 is coupled to an RF power generator 230 via a resonator 236, which is operated at the first frequency, the middle coil 204 to an RF power generator 232 via a resonator 238, operated at the second frequency, and the edge coil 206 to an RF power generator 234 via a resonator 240, operated at the third frequency. For example, the first frequency is at 13.56 MHz, the second at 2 MHz, and the third at 400 kHz.

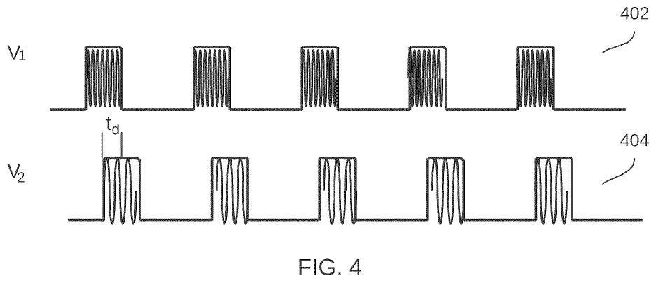

FIG. 4 illustrates exemplary pulse schemes for RF power generators 214 and 220 according to the first embodiment. The RF power waveform 402 for the RF power generator 214 is represented by V₁. The first RF power is divided between the center coil 202 and the edge coil 206 and is operated at the first frequency, such as 13.56 MHz. The first RF power is pulsed, characterized by the pulsing frequency and its duty cycle. The RF power waveform 404 for the RF power generator 220 is represented by V₂. The RF power generator 220 drives the middle coil 204 and may be operated at a substantially lower frequency, such as 2 MHz. The second RF power is also pulsed, as shown in FIG. 4. Each pulse in the second RF power waveform 404 overlaps with a pulse in the first RF power waveform 402. The pulse from waveform 404 may be designed with a delay, denoted as t_{d}. In some implementations, the pulses from the first and second RF power waveforms may be fully synchronized. A lower operating frequency alone for the RF power generator may encounter difficulties in igniting the plasma within the chamber 102, particularly for electronegative gases like chlorine. The overlap of the pulses ensures there is no need to re-ignite the plasma when transitioning from higher-frequency RF power to lower-frequency RF power. The lower frequency RF power enriches plasma modes with the chamber 102 which increases plasma density and improves its uniformity.

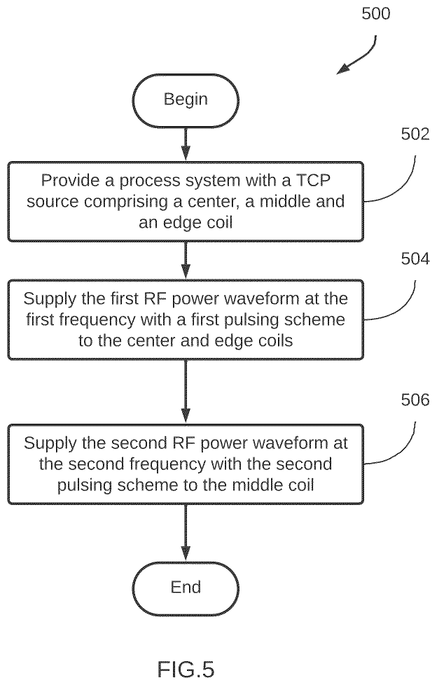

FIG. 5 presents a flowchart illustrating process 500, which describes operations of the first embodiment of the TCP source. Process 500 starts with step 502, in which process system 100 is provided. The process system 100 includes a TCP source comprising a center coil 202, a middle coil 204, and an edge coil 206. In step 504, the first RF power waveform 402 at the first frequency with the first pulsing scheme is supplied to the center and edge coils by the RF power generator 214. In step 506, the second RF power waveform 404 at the second frequency with the second pulsing scheme is supplied to the middle coil by the RF power generator 220. The pulse in the second RF power waveform overlaps with the pulse in the first RF power waveform. In one implementation, a delay is introduced for the pulses in the second RF power waveform. In another implementation, the pulses from the first waveform and the second waveform are fully synchronized.

1. A plasma source for a process system, comprising:
a plurality of coils including a center coil, a middle coil and an edge coil, placed atop a vacuum chamber;
a first RF power generator configured to supply a first RF power at a first frequency to the center coil;
a second RF power generator configured to supply a second RF power at a second frequency to the middle coil; and
a third RF power generator configured to supply the third RF power at a third frequency to the edge coil,
wherein the second frequency is substantially lower than the first frequency and the third frequency.

2. The plasma source of claim 1, wherein the first and the third RF power generators are the same generator with an RF power divider configured to distribute the RF power between the center and the edge coils.

3. The plasma source of claim 1, wherein the first RF power generator is operated at 13.56 MHz.

4. The plasma source of claim 1, wherein the third RF power generator is operated at 13.56 MH or 2 MHz.

5. The plasma source of claim 1, wherein the second RF power generator is operated at a substantially lower frequency than the first and the third RF power generators.

6. The plasma source of claim 5, wherein the second RF power generator is operated at a frequency selected from a group comprising 2 MHz, 1 MHz, 400 kHz, 100 kHz.

7. The plasma source of claim 1, wherein the first, second and third RF power generators are operated with respective pulsing schemes.

8. The plasma source of claim 7, wherein the pulses of the first and third RF power generators are synchronized.

9. The plasma source of claim 8, wherein each pulse from the second RF power generator overlaps with a pulse from the synchronized pulses of the first and third RF power generators.

10. The plasma source of claim 9, wherein the pulse from the second RF power generator has a delay relative to the synchronized pulses.

11. The plasma source of claim 1, wherein the center and edge coils comprise multiple turns.

12. The plasma source of claim 1, wherein the middle coil comprises a single turn.

13. The plasma source of the claim 1, wherein the plasma source is used in a process system for conducting an atomic layer etching (ALE) process.

14. The plasma source of claim 1, wherein the process chamber has a plasma volume of less than 10 liters.

15. A method for generating plasma within a process chamber, comprising:
a. providing the process chamber with a vacuum environment, wherein the plasma is generated by a plasma source, which includes a center coil, a middle and an edge coil;
b. receiving, by the center and the edge coils, an RF power waveform at a first frequency with a first pulsing scheme from a first RF power generator; and
c. receiving, by the middle coil, a second RF power waveform at a second frequency with a second pulsing scheme from a second RF power generator,
wherein each pulse from the second RF power waveform overlaps with a pulse from the first RF waveform.

16. The method of claim 15, wherein the pulse from the second RF power waveform overlaps with the pulse from the first RF power waveform with a delay.

17. The method of claim 15, wherein the pulse from the second RF power waveform is synchronized with the pulse from the first RF power waveform.

18. The method of claim 15, wherein the second RF power is at a substantially lower frequency than the first and third RF power frequencies.

19. The method of claim 15, wherein the second RF frequency is selected from a group comprising 2 MHz, 1 MHz, 400 kHz, and 100 kHz.

20. The method of claim 15, wherein the coils receive RF power with different phases.
